(19) United States
(12) Patent Application Publication
(10) Pub. No.: US 2013/0167916 A1
(43) Pub. Date: Jul. 4, 2013

(54) THIN FILM PHOTOVOLTAIC CELLS AND METHODS OF FORMING THE SAME

(71) Applicants: Wen-Chin LEE, Baoshan Township (TW); Liang-Sheng YU, Kaohsiung City (TW)

(72) Inventors: Wen-Chin LEE, Baoshan Township (TW); Liang-Sheng YU, Kaohsiung City (TW)

(73) Assignee: Taiwan Semiconductor Manufacturing Co., Ltd., Hsin-Chu (TW)

(21) Appl. No.: 13/338,292

(22) Filed: Dec. 28, 2011

(51) Int. Cl. H01L 31/0352; H01L 31/18

(52) U.S. Cl. 136/255; 438/98; 257/E31.032

(57) ABSTRACT

A thin film photovoltaic cell and method for forming the same. The thin film photovoltaic cell includes a first electrode layer formed on a substrate. An absorber layer of a first dopant-type is formed on the first electrode layer. The absorber layer has an opening extending partially into the absorber layer from a top surface of the absorber layer. The opening has side walls and a bottom surface. A buffer layer of a second dopant type is formed on the top surface of the absorber layer, the side walls of the opening and the bottom surface of the opening A second electrode layer is formed on the buffer layer.

### FIELD OF THE INVENTION

The present disclosure is directed generally to photovoltaic solar cells and more particularly to thin film photovoltaic cells and methods of forming the same.

### DESCRIPTION OF THE RELATED ART

Thin film photovoltaic (PV) solar cells are one class of energy source devices which harness a renewable source of energy in the form of light that is converted into useful electrical energy which may be used for numerous applications. Thin film PV cells are multi-layered semiconductor structures formed by depositing various thin layers and films of semiconductor and other materials on a substrate. These PV cells may be made into light-weight flexible sheets in some forms comprised of a plurality of individual electrically interconnected cells. The attributes of light weight and flexibility gives thin film PV cells broad potential applicability as an electric power source for use in portable electronics, aerospace, and residential and commercial buildings where they can be incorporated into various architectural features such as roof shingles, facades and skylights.

Thin film PV cell semiconductor packages generally include a bottom contact or electrode formed on a substrate, a p-n junction area formed from an absorber layer and a buffer layer of opposite dopant types above the bottom electrode, a top contact or electrode formed above the p-n junction area and interconnects (IC) formed to connect the top and bottom electrodes.

### BRIEF DESCRIPTION OF THE DRAWINGS

Various aspects of the present disclosure will be or become apparent to one with skill in the art by reference to the following detailed description when considered in connection with the accompanying exemplary non-limiting embodiments.

FIG. 1a is a cross-sectional side view of a thin film photovoltaic cell having a substrate, first electrode layer and an absorber layer according to an embodiment of the present disclosure.

FIG. 1b is a cross-sectional side view of a thin film photovoltaic cell having a substrate, first electrode layer, an absorber layer and a buffer layer according to an embodiment of the present disclosure.

FIG. 2 is a cross-sectional side view of a thin film photovoltaic cell according to an embodiment.

FIG. 3 is a flow chart illustrating a method for forming a thin film photovoltaic cell according to an embodiment of the present disclosure.

FIG. 4 is a cross-sectional side view of a thin film photovoltaic cell according to an embodiment.

FIG. 5 is a cross-sectional side view of a thin film photovoltaic cell having a substrate, first electrode layer and an absorber layer according to an embodiment of the present disclosure.

FIG. 6 is a cross-sectional side view of a thin film photovoltaic cell having a substrate, first electrode layer and an absorber layer according to an embodiment of the present disclosure.

FIG. 7 is a flow chart illustrating a method for forming a thin film photovoltaic cell according to an embodiment of the present disclosure.

### DETAILED DESCRIPTION OF THE EXAMPLES

An improved thin film PV cell is described below, that increases the effective p-n junction area in a manner that increases its light absorption capability. The thin film PV cell fabrication processes described herein may be performed using any suitable commercially available equipment commonly used in the art to manufacture thin film PV cells, or alternatively, using future developed equipment.

The size of the p-n junction area, and its light absorption capability, directly correlates to the available power and efficiency of the PV cell. The effective size of the p-n junction area is generally limited by the surface area of the thin-film PV cells.

With reference to the Figures, where like elements have been given like numerical designations to facilitate an understanding of the drawings, the various embodiments of a thin film photovoltaic (PV) cell and methods of forming the same are described.

The following description is provided as an enabling teaching of a representative set of examples. Those skilled in the art will recognize that many changes can be made to the embodiments described herein while still obtaining beneficial results. It will also be apparent that some of the desired benefits discussed below can be obtained by selecting some of the features or steps discussed herein without utilizing other features or steps. Accordingly, those who work in the art will recognize that many modifications and adaptations, as well as subsets of the features and steps described herein are possible and may even be desirable in certain circumstances. Thus, the following description is provided as illustrative and is not limiting.

This description of illustrative embodiments is intended to be read in connection with the accompanying drawings, which are to be considered part of the entire written description. In the description of embodiments disclosed herein, any reference to direction or orientation is merely intended for convenience of description and is not intended in any way to limit the scope of the present invention. Relative terms such as “lower,” “upper,” “horizontal,” “vertical,”, “above,” “below,” “up,” “down,” “top” and “bottom” as well as derivative thereof (e.g., “horizontally,” “downwardly,” “upwardly,” etc.) should be construed to refer to the orientation as then described or as shown in the drawing under discussion. These relative terms are for convenience of description only and do not require that the apparatus be constructed or operated in a particular orientation. Terms such as “attached,” “affixed,” “connected” and “interconnected,” refer to a relationship wherein structures are secured or attached to one another either directly or indirectly through intervening structures, as well as both movable or rigid attachments or relationships, unless expressly described otherwise. The term “adjacent” as used herein to describe the relationship between structures/components includes both direct contact between the respective structures/components referenced and the presence of other intervening structures/components between respective structures/components. Moreover, various features and benefits are illustrated by reference to the exemplary embodiments. Accordingly, the subject matter of this disclosure and the appended claims are expressly not limited to such preferred embodiments.

As used herein, use of a singular article such as “a,” “an” and “the” is not intended to exclude pluralities of the article's object unless the context clearly and unambiguously dictates otherwise.

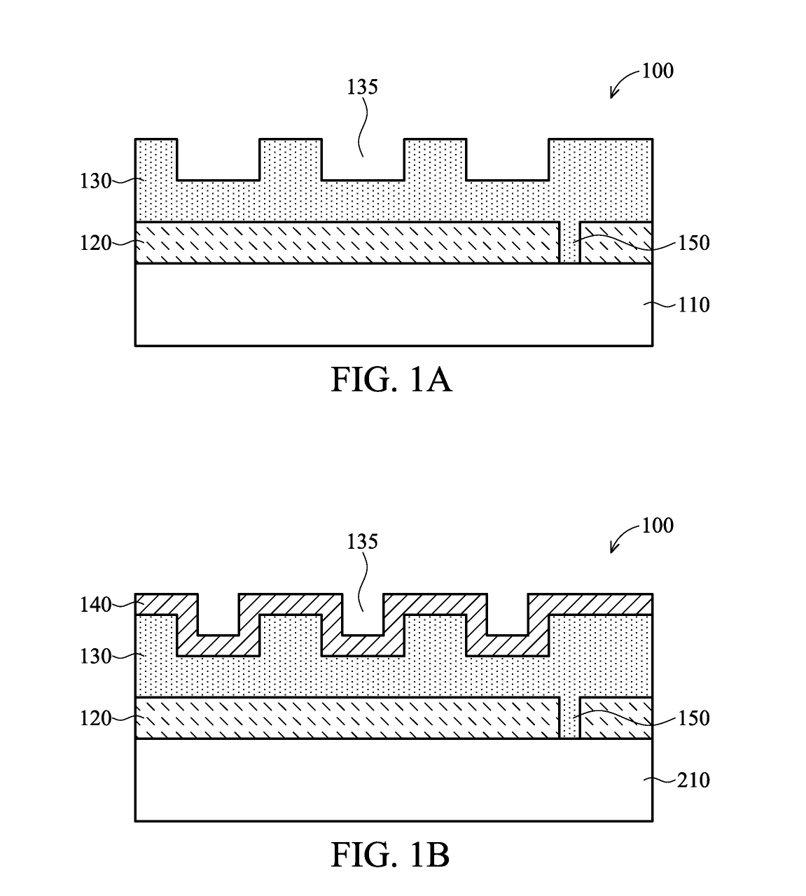

With reference now to FIG. 1a, an embodiment of a thin film PV cell 100 having an absorber layer 130 of a first dopant type formed in-situ during the process of forming the PV cell is provided. PV cell 100 includes a substrate 110, a first electrode layer 120 formed thereon, and an absorber layer 130 of a first dopant type formed on the first electrode layer. The absorber layer 130 has an opening 135 that extends partially into the absorber layer from a top surface of the absorber layer. The opening 135 has a bottom surface and side walls. In a preferred embodiment, the thickness of the bottom surface of the opening 135 and a bottom surface of the absorber layer 130 is approximately 0.5 microns (μm) (e.g. from 0.5 μm to 0.525 μm) or more. In some embodiments, the thickness of the bottom surface of the opening 135 and a bottom surface of the absorber layer 130 may be a thickness ranging from (and including) about 0.5 to 3 μm (e.g. 0.475 to 3.15 μm). In some embodiments, the thickness may range from (and include) about 1 to 2 μm (e.g. 0.95 to 2.1 μm).

Thicknesses less than approximately 0.5 μm may result in poor light absorption capabilities in absorber layer 130, a reduction in efficiency, and/or leakage current traveling into the substrate 110. Thicknesses substantially greater than approximately 0.5 μm may be less desirable due to cost considerations. In an embodiment, the aspect ratio of the opening is between approximately 0.01 (e.g. 0.0095) and approximately 2 (e.g. 2.1). As used herein, the aspect ratio of the opening 135 is defined as the height of the opening 135 divided by the width of the opening 135. The opening 135 may preferably have a height ranging from (and including) about 0.5 to 2.5 μm (e.g. 0.475 to 2.625 μm) and have a width ranging from (and including) about 20-30 μm (e.g. 19 to 31.5 μm). In some embodiments, the opening 135 may have a width ranging from (and including) about 0.1 μm to 10 μm (e.g. 0.095 to 10.5 μm). In other embodiments, the opening 135 may have a width ranging from (and including) about 0.4 μm to 200 μm (e.g. 0.38 to 105 μm). In an embodiment, the opening 135 may extend the length of the substrate 110. In another embodiment, the opening 135 may extend the width of the substrate 110. In a further embodiment, the opening 135 may be localized along the surface area of the substrate 110. The opening 135 can increase the p-n junction area (e.g. overall interface area of the absorber layer 130 and the buffer layer 140). As illustrated in FIG. 1a, the absorber layer may have a plurality of openings 135 extending partially into the absorber layer 130 from a top surface of the absorber layer 130. Each of the openings 135 has side walls and a bottom surface. In an embodiment, each of the plurality of openings 135 may have an uniform aspect ratio. In another embodiment, the aspect ratio may vary between one or more of the plurality of openings 135 within the same PV cell.

Suitable materials that may be used for substrate 110 include for example without limitation glass such as, soda lime glass, ceramic, metals such as thin sheets of stainless steel and aluminum, or polymers such as polyamides, polyethylene terephthalates, polyethylene naphthalates, polymeric hydrocarbons, cellulosic polymers, polycarbonates, polyethers, combinations thereof, and/or others. In an embodiment, substrate 110 may be glass. First electrode layer 120 may be made from any suitable electrically conductive metallic and semiconductor material including, without limitation, aluminum, silver, tin, titanium, nickel, stainless steel, or zinc telluride. In an embodiment, molybdenum is used as the first electrode layer 120 material. In another embodiment, a barrier layer is formed on the substrate 110 and the first electrode layer 120 is formed on the barrier layer. The barrier layer is formed to control sodium (Na) diffusion from glass and prevent other contamination from the substrate 110. The barrier layer may comprise a water insoluble material including, but not limited to, stable oxide compounds.

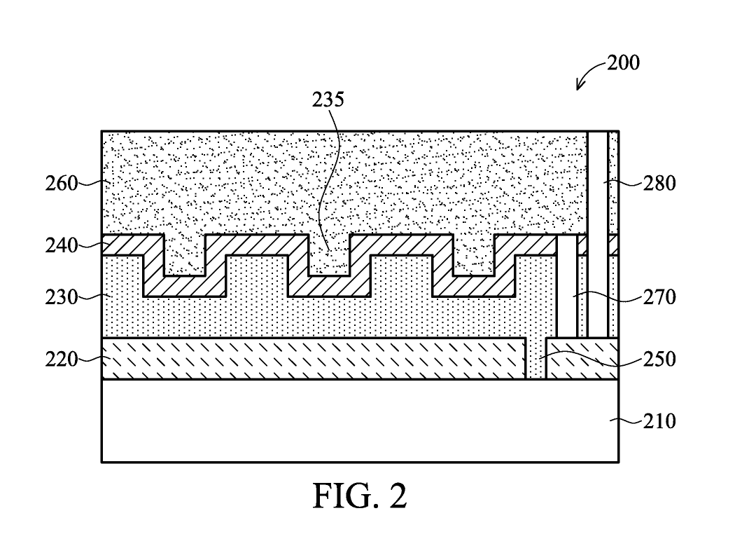

In an embodiment, the absorber layer 130 may comprise a p-type material. For example, absorber layer 130 may be a p-type chalcogenide material. In a further embodiment, the absorber layer 130 may be a CIGS Cu(In,Ga)Se₂ material. In other embodiments, chalcogenide materials including, but not limited to, Cu(In,Ga)(Se, S)₂ or “CIGSS,” CuInSe₂, CuGaSe₂, CuInS₂, and Cu(In,Ga)S₂. may be used as an absorber layer 130 material. Suitable p-type dopants that may be used for forming absorber layer 30 include without limitation boron (B) or other elements of group II or III of the periodic table. In another embodiment, the absorber layer may comprise an n-type material including, without limitation, cadmium sulfide (CdS). PV cell 100 may include microchannels which are patterned and scribed as openings defining a vertical channel extending into the semiconductor structure to interconnect the various conductive material layers and to separate adjacent solar cells. These micro-channels or “scribe lines” as commonly referred to in the art are given “P” designations related to their function and step during the semiconductor solar cell fabrication process. For example, P1 scribe line 150 and P3 scribe line 280 (FIG. 2) are essentially for cell isolation. A P2 scribe line 270 (FIG. 2) forms a connection between the first and second electrode layers. In the illustrated embodiment of FIG. 1a, the absorber layer 130 is connected to the substrate 110 through an opening defining a vertical channel (P1 scribe line 150) that extends through the first electrode layer 120.

FIG. 1b illustrates a buffer layer 140 of a second dopant type formed on the top surface of the absorber layer 130 to create an electrically active p-n junction area of thin film PV cell 100. In the illustrated embodiment, the buffer layer 140 is formed on the bottom surface and side walls of each of the plurality of openings 135 extending partially into the absorber layer 130. In an embodiment, the buffer layer 140 may comprise an n-type material including, without limitation, cadmium sulfide (CdS) and the absorber layer 130 may comprise a p-type material including, without limitation, CIGS. In some embodiments, the buffer layer may be surface doped with any suitable n-type dopant including, but not limited to, aluminum, phosphorous, arsenic or other elements of groups V or VI of the periodic table of elements. In the illustrated embodiment, the buffer layer 140 conforms to the top surface of the absorber layer 130 and the bottom surface and side walls of each of the plurality of openings 135 extending partially into the absorber layer 130. In another embodiment, the buffer layer 140 is non-conformal. As used herein, the step coverage ratio is defined as the ratio of the buffer layer 140 thickness on the side wall of the opening 135 to the buffer layer 140 thickness on the top surface of the absorber layer 130. The bottom coverage ratio is defined as the ratio of the buffer layer 140 thickness on the bottom surface of the opening 135 to the buffer layer 140 thickness on the top surface of the absorber layer 130. Preferably, the step coverage ratio is approximately 0.80 (e.g. 0.76) or more and the bottom coverage ratio is also approximately 0.80 (e.g. 0.76) or more to minimize the effects of sheet resistance (Rsh). In other embodiments, the step and bottom coverage ratios range from (and include) about 0.6 to 1.0 (e.g. 0.55 to 1.0). As illustrated in FIG. 1b, the formation of the buffer layer on the top surface of the absorber layer 130, the side walls of the opening 135 and the bottom surface of the opening 135 may increase the effective size of the p-n junction area significantly without any increase in PV cell size. Therefore, an increase in power collection is possible without any increase in PV cell size and it is possible to achieve the same amount of power as conventional PV cells using a smaller PV cell size according to the present invention. In another embodiment, the thin film PV cell may comprise a single, or multi (e.g. double or triple) p-n junction area wherein the opening is formed in one or more of the p-n junction areas.

With reference now to FIG. 2, an embodiment of a thin film PV cell 200 is provided having a second electrode layer 260 formed on top of the buffer layer 240 to collect current (electrons) from the cell and preferably absorb a minimal amount of light which passes through to the absorber layer 230. In an embodiment, the second electrode layer 260 may comprise a light transmittance conductive oxide (TCO) material. For example, the TCO material used for second electrode layer 260 may include, without limitation, zinc oxide (ZnO), fluorine tin oxide (“FTO” or SnO₂:F), indium tin oxide (“ITO”), indium zinc oxide (“IZO”), antimony tin oxide (ATO), a carbon nanotube layer, or any other suitable coating materials possessing the desired properties for the second electrode layer. The second electrode layer 260 may be a composition of multi-layers with or without one or more types of dopants and/or concentrations. In one preferred embodiment, the TCO used is ZnO. In an embodiment, the second electrode layer 260 is n-type doped. Suitable n-type dopants may include, without limitation, aluminum, phosphorous, arsenic or other elements of groups V or VI of the periodic table of elements. The second electrode layer 260 may have a thickness ranging from about and including 0.1 to 10 μm (e.g. 0.0095 to 10.5 μm). Preferably, the second electrode layer 260 has a thickness ranging from about and including 0.5 to 3 μm (e.g. 0.055 to 3.15 μm).

In the illustrated embodiment, PV cell 200 further includes scribe lines 270 and 280. Absorber material is removed from P2 scribe line 270 to electrically interconnect the second electrode layer to the first electrode layer, thereby preventing the intermediate buffer layer from acting as a barrier between the second and first electrode layers. As shown in FIG. 2, P3 scribe line 280 may extend completely through the second electrode layer 260, buffer layer 240, and absorber layer 230 to the first electrode layer to isolate each cell defined by the scribe lines 250 and 270. The scribe line 270 may be at least partially filled with material from the second electrode layer on the side walls of the opening defining the vertical channel extending through the buffer 240 and absorber 230 layers and on the top surface of the first electrode layer 220.

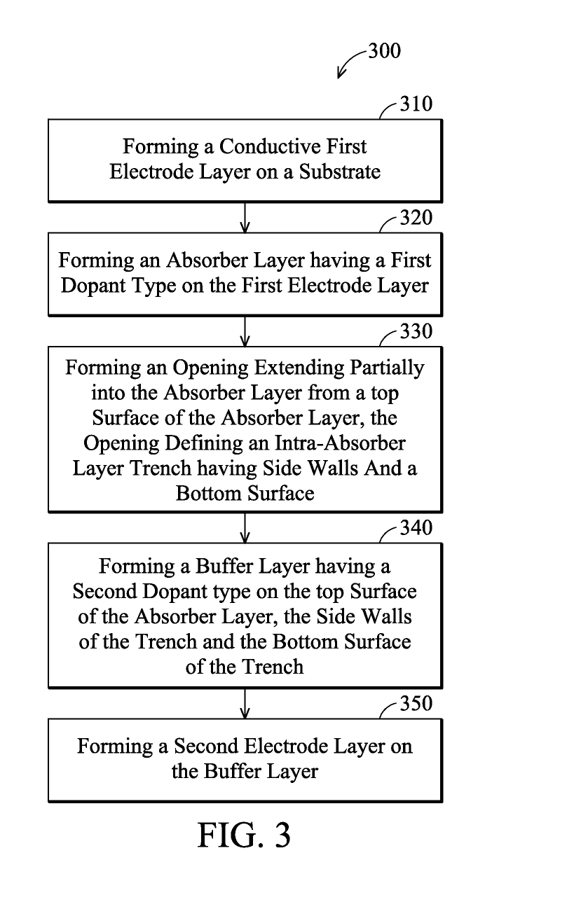

FIG. 3 is a flow chart showing a method 300 of forming a thin film PV cell 100 (200) according to some embodiments. In an embodiment, a substrate 110 (210) is provided. At block 310, a first conductive electrode layer 120 (220) is formed on substrate 110 (210) by any suitable method including without limitation sputtering, atomic layer deposition (ALD), chemical vapor deposition (CVD), or other techniques. Substrate 110 (210) may be cleaned prior to the step of forming the first electrode layer 120 (220) thereon. At block 320, an absorber layer 130 (230) having a first dopant type is formed on the first electrode layer 120 (220). Absorber layer 130 (230) may be formed by ALD, CVD; metal oxide CVD, chemical bath deposition (CBD) or any other suitable method. In some embodiments, an opening 150 (250) may be formed in the first electrode layer 120 (220) and may define a vertical channel (e.g. P1 scribe line) extending through the first electrode layer 120 (220). The opening 150 (250) may expose the top surface of substrate 110 (210).

Any suitable scribing method may be used to form opening 150 (250) including, without limitation, mechanical scribing with a stylus or laser scribing. Opening 150 (250) may also be formed using photolithography. The opening 150 (250) in the first electrode layer 120 (220) may be at least partially filled with material from the absorber layer 130 (230) during formation of the absorber layer 130 (230) to connect the absorber layer (130 (230) to the substrate 110 (210).

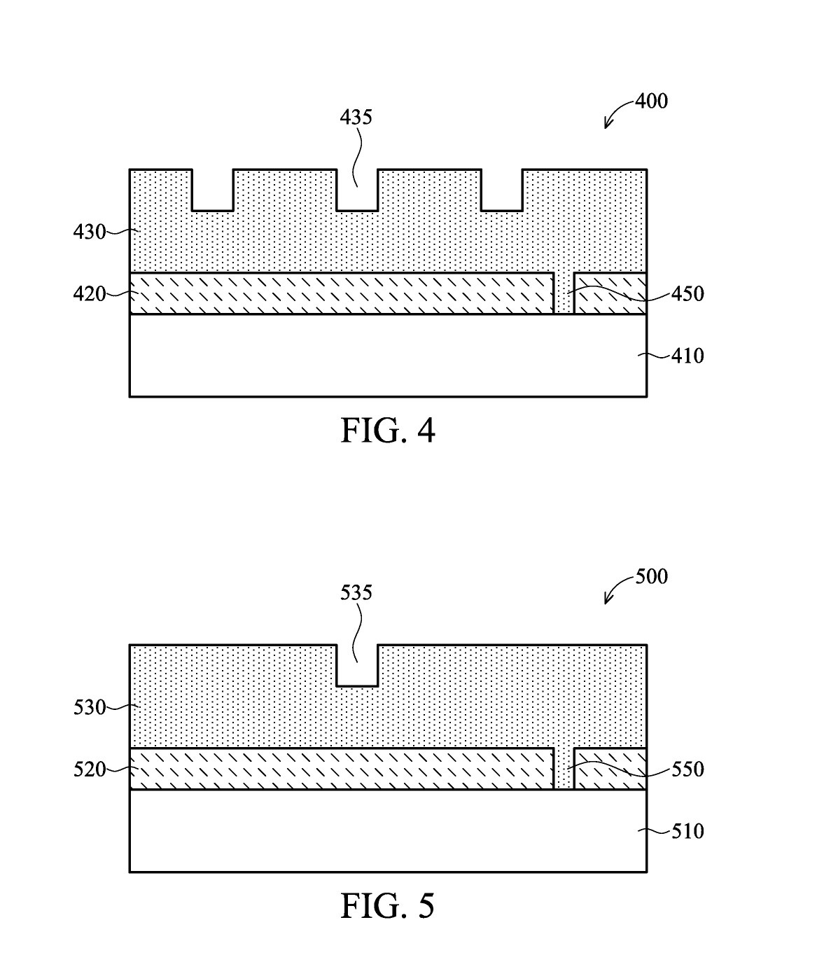

At block 330, an opening is formed extending partially into the absorber layer 130 (230) from a top surface of the absorber layer 130 (230). The opening defines an intra-absorber layer trench 135 (235) having side walls and a bottom surface. The intra-absorber layer trench 135 (235) may be formed by a photolithographic process, scribing (laser or mechanical), a dry etch process, a wet etch process or any other suitable method. In some embodiments, a plurality of openings in the top surface of the absorber layer 130 (230) may be formed to define a plurality of intra-absorber layer trenches 135 (235), each opening extending partially into the absorber layer 130 (230) from the top surface of the absorber layer 130 (230). In some embodiments, a photolithographic, dry etch, or wet etch process may be used to define the aspect ratio and/or density of one or more intra-absorber layer trenches 135 (235) formed in the absorber layer 130 (230). The inventors have observed that, for a dry or wet etch process, the etching rate at intra-absorber layer trench areas of varying density may be different. With reference to FIG. 4, a dry or wet etch process may be used to form a higher density area of intra-absorber layer trenches 435 in the PV cell 400. As shown, the plurality of intra-absorber layer trenches 435 in the high density area of the PV cell 400 may have a lower aspect ratio. With reference now to FIG. 5, a dry or wet etch process may be used to form a lower density (loose or iso) intra-absorber layer trench 535 area in the PV cell 500. As illustrated, the intra-absorber layer trench 535 in the loose or isolated area of the PV cell 500 may have a higher aspect ratio relative to an aspect ratio in a higher density intra-absorber layer trench area (FIG. 4.)

Preferably, the opening in the top surface of the absorber layer is formed at block 330 such that the thickness between the bottom surface of the trench 135 (235) and a bottom surface of the absorber layer 130 (230) is approximately 0.5 microns (μm) or more. In other embodiments, the opening in the top surface of the absorber layer 130 (230) is formed such that the aspect ratio of the intra-absorber layer trench 135 (235) is between approximately 0.01 and approximately 2. In some representative embodiments, without limitation, the opening in the top surface of the absorber layer 130 (230) is formed such that height of an intra-absorber layer trench 135 (235) ranges from about and including 0.5 μm to 2.5 μm and such that the width of an intra-absorber layer trench 135 (235) ranges from about and including 20 μm to 30 μm. In other embodiments, the opening in the top surface of the absorber layer 130 (230) is formed such that the width of the intra-absorber layer trench 135 (235) ranges from about and including 0.4 μm to 100 μm.

At block 340, a buffer layer 140 (240) having a second dopant type is formed on the top surface of the absorber layer 130 (230), the side walls of the trench 135 (235) and the bottom surface of the trench 135 (235) to create an electrically active p-n junction area. Buffer layer 140 (240) may be formed any suitable method. In one embodiment, buffer layer 140 (240) may be formed by an electrolyte chemical bath deposition (CBD) process for forming such layers using an electrolyte solution that contains sulfur. In other embodiments, buffer layer 140 (240) may be formed by ALD, CVD; or metal oxide CVD. Preferably, the buffer layer 140 (240) is formed at block 340 such that the step coverage ratio and the bottom coverage ratio are approximately 0.80 or more to minimize the effects of sheet resistance (Rsh). In some representative embodiments, without limitation, buffer layer 140 may preferably have a thickness ranging from about and including 0.001 to 2 microns (μm). In some embodiments, an opening 270 in the buffer layer 140 (240) and the absorber layer 130 (230) may be formed such that the opening defines a vertical channel (e.g. P2 scribe line) extending through the buffer 140 (240) and absorber 130 (230) layers. The opening 270 may expose the top surface of the first electrode layer 120 (220). Any suitable scribing method commonly used in the art may be used to form opening 270 including, without limitation, mechanical scribing with a stylus or laser scribing. Opening 270 may also be formed using photolithography.

At block 350, a second electrode layer 260 may be formed on the buffer layer 140 (240) for collecting current from the cell and preferably absorbing a minimal amount of light which passes through to absorber layer 130 (230). The second electrode layer may be deposited by any suitable method including without limitation sputtering, atomic layer deposition (ALD), chemical vapor deposition (CVD), or other techniques. In embodiments having an opening 270 in the buffer layer 140 (240) and the absorber layer 130 (230), the opening 270 may be at least partially filled during formation of the second electrode layer 260 with material from the second electrode layer 260 to electrically connect the second electrode layer 260 to the first electrode layer 120 (220). In some embodiments, the top surface of the second electrode layer 260 is planar (FIG. 2).

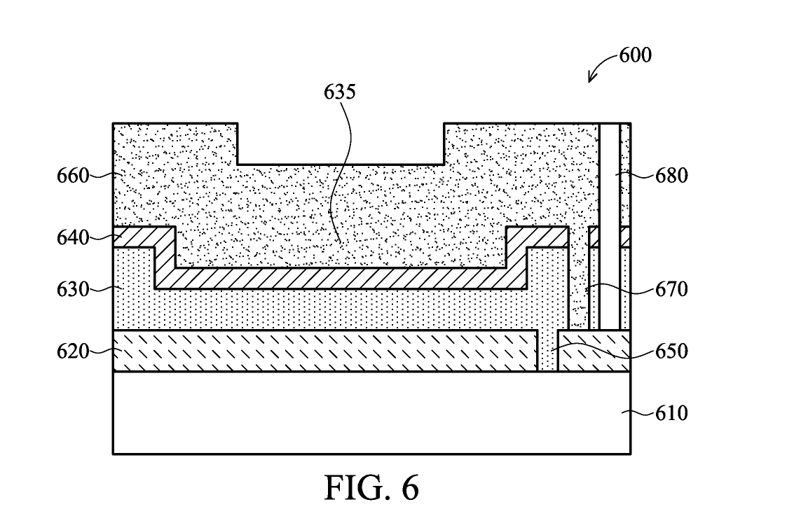

With reference to FIG. 6, another embodiment of a thin film PV cell is provided. In the illustrated embodiment, the opening in the top surface of the absorber layer 630 is formed such that the width of the intra-absorber layer trench 635 is larger relative to the width of the intra-absorber layer trenches 135 (235) shown, for example, in FIGS. 1a, 1b and 2. As shown in FIG. 6, the top surface of the second electrode layer 660 may be non-planar. The inventors have observed that as the width of the intra-absorber layer trench 635 is increased, the second electrode layer 660 may partially conform with the intra-absorber layer shape, further improving light collection in the PV cell. Preferably, the second electrode layer 260 (660) is continuous over the surfaces of the one or more intra-absorber layer trenches 235 (635). In some embodiments, at block 350, the second electrode layer 260 is formed such that it has a thickness ranging from about and including 0.1 to 3 μm. Preferably, the second electrode layer 260 is formed such that it has a thickness ranging from about 0.5 to about 3 μm.

In some embodiments, an opening 280 (680) may be formed, defining a vertical channel (e.g. P3 scribe line) extending through the second electrode layer 260 (660), the buffer layer 240 (640) and the absorber layer 230 (630). The opening 280 may expose the top surface of the first electrode layer 220 (620). Any suitable method may be used to cut the opening 280 as described above including, but not limited to, mechanical or laser scribing or photolithography.

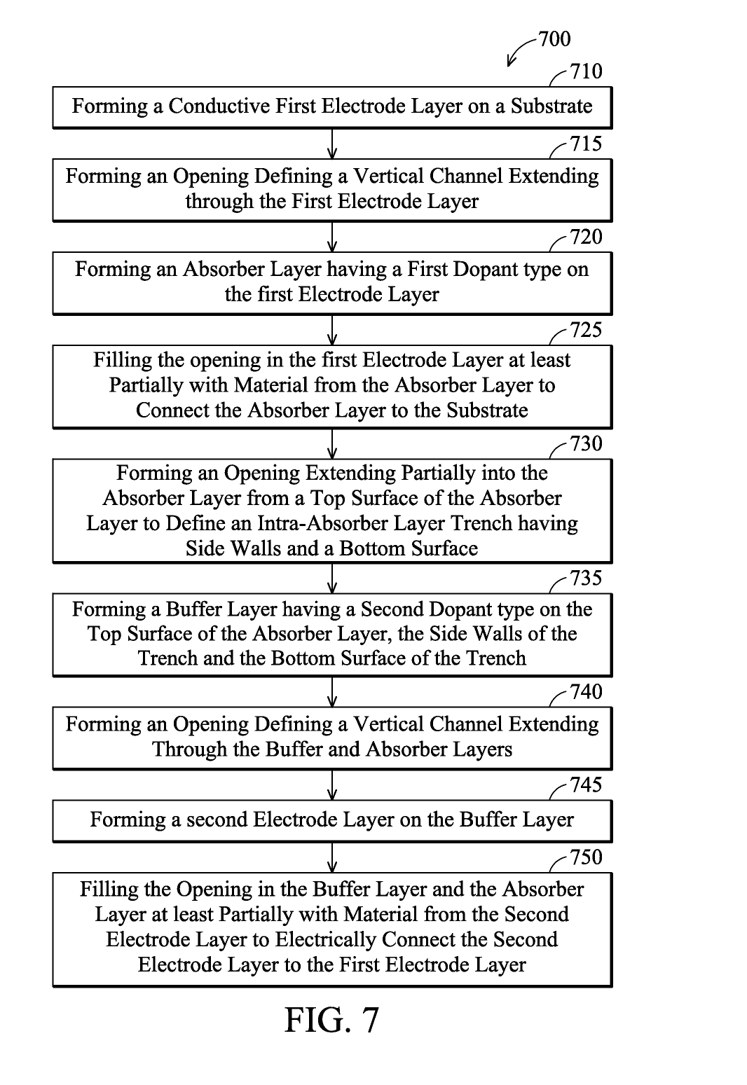

FIG. 7 is a flow chart showing a method of forming a thin film PV cell 200 (600) according to some embodiments. At block 710, a conductive first electrode layer 220 (620) is formed on a substrate 210 (610) as described above. At block 715, an opening 250 (650) (e.g. P1 scribe line) defining a vertical channel extending through the first electrode layer is formed as described above. At block 720, an absorber layer 230 (630) having a first dopant type is formed on the first electrode layer as described above. At block 725, the opening 250 (650) in the first electrode layer 220 (620) is filled, as described above, at least partially with material from the absorber layer 230 (630) during formation of the absorber layer 230 (630) to connect the absorber layer 230 (630) to the substrate 210 (610). At block 730, an opening is formed extending partially into the absorber layer 230 (630) from a top surface of the absorber layer 230 (630) as described above to define an intra-absorber layer trench 235 (635) having side walls and a bottom surface. At block 740, a buffer layer 240 (640) having a second dopant type is formed on the top surface of the absorber layer 230 (630), the side walls of the trench 235 (635), and the bottom surface of the trench 235 (635), to create a p-n junction area. At block 745, an opening 270 (670) is formed defining a vertical channel extending through the buffer 240 (640) and absorber 230 (630) layers as described above. At block 750, a second electrode layer 260 (660) on the buffer layer 240 (640) as described above. At block 760, the opening 270 (670) in the buffer layer 240 (640) and the absorber layer 230 (630) is filled, as described above during deposition of the second electrode layer 260 (660), at least partially with material from the second electrode layer 260 (660) to electrically connect the second electrode layer 260 (660) to the first electrode layer 220 (620).

As shown by the various configurations and embodiments illustrated in FIGS. 1a-7, various improved thin film photovoltaic cells and methods for forming the same have been described.

One embodiment provides a thin film photovoltaic cell including a first electrode layer formed on a substrate. The embodiment also includes an absorber layer of a first dopant-type formed on the first electrode layer. The absorber layer has an opening extending partially into the absorber layer from a top surface of the absorber layer. The opening has side walls and a bottom surface. The embodiment also includes a buffer layer of a second dopant type formed on the top surface of the absorber layer, the side walls of the opening and the bottom surface of the opening The embodiment further includes a second electrode layer formed on the buffer layer.

Another embodiment provides a method for forming a thin film photovoltaic cell including forming a conductive first electrode layer on a substrate. An absorber layer is formed having a first dopant type on the first electrode layer. An opening is formed extending partially into the absorber layer from a top surface of the absorber layer. The opening defines an intra-absorber layer trench having side walls and a bottom surface. The embodiment also includes forming a buffer layer having a second dopant type on the top surface of the absorber layer, the side walls of the trench and the bottom surface of the trench. A second electrode layer is formed on the buffer layer.

A further embodiment provides a method for forming a thin film photovoltaic cell including forming a conductive first electrode layer on a substrate An opening is formed defining a vertical channel extending through the first electrode layer. The embodiment also includes forming an absorber layer having a first dopant type on the first electrode layer and filling the opening in the first electrode layer at least partially with material from the absorber layer to connect the absorber layer to the substrate. An opening is formed extending partially into the absorber layer from a top surface of the absorber layer to define an intra-absorber layer trench having side walls and a bottom surface. A buffer layer is formed having a second dopant type on the top surface of the absorber layer, the side walls of the trench and the bottom surface of the trench. The embodiment further includes forming an opening defining a vertical channel extending through the buffer and absorber layers and forming a second electrode layer on the buffer layer. The opening in the buffer layer and the absorber layer is filled at least partially with material from the second electrode layer to electrically connect the second electrode layer to the first electrode layer.

While preferred embodiments have been described, it is to be understood that the embodiments described are illustrative only and that the scope of the subject matter is to be accorded a full range of equivalents, many variations and modifications naturally occurring to those of skill in the art from a perusal hereof.

Furthermore, the above examples are illustrative only and are not intended to limit the scope of the disclosure as defined by the appended claims. It will be apparent to those skilled in the art that various modifications and variations can be made in the methods of the present subject matter without departing from the spirit and scope of the disclosure. Thus, it is intended that the claims cover the variations and modifications that may be made by those of ordinary skill in the art.

What we claim is:

1. A thin film photovoltaic cell, comprising:
a first electrode layer formed on a substrate;
an absorber layer of a first dopant-type formed on the first electrode layer, the absorber layer having an opening extending partially into the absorber layer from a top surface of the absorber layer, the opening having side walls and a bottom surface;
a buffer layer of a second dopant type formed on the top surface of the absorber layer, the side walls of the opening and the bottom surface of the opening; and
a second electrode layer formed on the buffer layer.

2. The photovoltaic cell of claim 1, wherein the absorber layer further comprises a plurality of openings extending partially into the absorber layer from the top surface of the absorber layer.

3. The photovoltaic cell of claim 1, wherein the thickness between the bottom surface of the opening and a bottom surface of the absorber layer is approximately 0.5 μm or more.

4. The photovoltaic cell of claim 3, wherein the aspect ratio of the opening is between approximately 0.01 and approximately 2.

5. The photovoltaic cell of claim 1, wherein a step coverage ratio of the cell is approximately 0.80 or more and a bottom coverage ratio of the cell is approximately 0.80 or more.

6. The photovoltaic cell of claim 1, wherein a first surface of the second electrode layer is non-planar.

7. The photovoltaic cell of claim 1, further comprising:
a barrier layer formed on the substrate, wherein the first electrode layer is formed on the barrier layer.

8. The photovoltaic cell of claim 1, wherein the absorber layer comprises a p-type chalcogenide material.

9. The photovoltaic cell of claim 9, wherein the buffer layer comprises an n-type material.

10. The photovoltaic cell of claim 1, wherein the buffer layer is conformal.

11. The photovoltaic cell of claim 1, wherein the second electrode layer comprises a light transmittance conductive oxide material.

12. A method for forming a thin film photovoltaic cell, comprising:
forming a conductive first electrode layer on a substrate;
forming an absorber layer having a first dopant type on the first electrode layer;
forming an opening extending partially into the absorber layer from a top surface of the absorber layer, the opening defining an intra-absorber layer trench having side walls and a bottom surface;
forming a buffer layer having a second dopant type on the top surface of the absorber layer, the side walls of the trench and the bottom surface of the trench; and
forming a second electrode layer on the buffer layer.

13. The method of forming the thin film photovoltaic cell of claim 12, further comprising:
forming the opening in the top surface of the absorber layer such that the thickness between the bottom surface of the trench and a bottom surface of the absorber layer is approximately 0.5 μm or more.

14. The method of forming the thin film photovoltaic cell of claim 13, further comprising:
forming the opening in the top surface of the absorber layer such that the aspect ratio of the intra-absorber layer trench is between approximately 0.01 and approximately 2.

15. The method of forming the thin film photovoltaic cell of claim 13, further comprising:
forming a plurality of openings in the top surface of the absorber layer to define a plurality of intra-absorber layer trenches, each opening extending partially into the absorber layer from the top surface of the absorber layer.

16. The method of forming the thin film photovoltaic cell of claim 13, further comprising:
forming an opening in the first electrode layer, the opening defining a vertical channel extending through the first electrode layer; and
filling the opening in the first electrode layer at least partially with material from the absorber layer to connect the absorber layer to the substrate.

17. The method of forming the thin film photovoltaic cell of claim 13, further comprising:
forming an opening in the buffer layer and the absorber layer, the opening defining a vertical channel extending through the buffer and absorber layers; and
filling the opening in the buffer layer and the absorber layer at least partially with material from the second electrode layer to electrically connect the second electrode layer to the first electrode layer.

18. The method of forming the thin film photovoltaic cell of claim 13, further comprising:
forming an opening defining a vertical channel extending through the second electrode layer, the buffer layer and the absorber layer.

19. The method of forming the thin film photovoltaic cell of claim 13, wherein a first surface of the second electrode layer is non-planar.

20. A method for forming a thin film photovoltaic cell, comprising:
forming a conductive first electrode layer on a substrate;
forming an opening defining a vertical channel extending through the first electrode layer;
forming a absorber layer having a first dopant type on the first electrode layer;
filling the opening in the first electrode layer at least partially with material from the absorber layer to connect the absorber layer to the substrate;
forming an opening extending partially into the absorber layer from a top surface of the absorber layer to define an intra-absorber layer trench having side walls and a bottom surface;
forming a buffer layer having a second dopant type on the top surface of the absorber layer, the side walls of the trench and the bottom surface of the trench;
forming an opening defining a vertical channel extending through the buffer and absorber layers;
forming a second electrode layer on the buffer layer; and
filling the opening in the buffer layer and the absorber layer at least partially with material from the second electrode layer to electrically connect the second electrode layer to the first electrode layer.
